(19) United States
(12) Patent Application Publication
(10) Pub. No.: US 2014/0300358 A1
(43) Pub. Date: Oct. 9, 2014

(54) SYSTEM AND METHOD FOR REAL-TIME NOISE REDUCTION IN MRI DATA ACQUISITION

(71) Applicant: ASPECT IMAGING LTD., Shoham (IL)

(72) Inventor: Uri RAPOPORT, Moshav Ben Shemen (IL)

(21) Appl. No.: 13/939,636

(22) Filed: Jul. 11, 2013

Related U.S. Application Data
(60) Provisional application No. 61/809,437, filed on Apr. 8, 2013.

(51) Int. Cl. G01R 33/56

(52) U.S. Cl. CPC G01R 33/56
USPC 324/311; 324/322; 324/307

(57) ABSTRACT

A system for determining the level of shielding in a magnetic resonance imaging (MRI) apparatus and for real-time reduction of noise produced during MRI data acquisition. The system includes: at least one antenna; data acquirer in communication with the at least one antenna and in communication with the RF pulse generator; and a synchronizer for synchronizing the acquisition of data by the data acquirer with MRI pulses being produced by the MRI apparatus.

### FIELD OF THE INVENTION

This invention relates to systems and methods for reducing noise in MRI images. In particular, it relates to systems and methods that perform real-time noise reduction during data acquisition rather than during image reconstruction.

### BACKGROUND OF THE INVENTION

The application of NMR (nuclear magnetic resonance) known as MRI (magnetic resonance imaging) is a widely used technique in a variety of fields, particularly in medicine. The MRI technique relies on the extraction of a signal that represents a very small physical change in the system being studied. Thus, even small amounts of noise can have major effects on the signal and on the image that is finally derived from the signal. Even though MRI instruments are nominally shielded against RF interference and other sources of noise, the shielding is not always perfect, thereby allowing noise (especially from other instruments that may be nearby) to appear on the signal.

If the noise interfering with the MRI signal is not observed in real time during the signal acquisition procedure, its presence will only be known by its effects on the final reconstructed image. If the noise is only discovered during image reconstruction, it may be difficult or impossible to correct the resulting degradation of the quality of the image.

There is thus a long-felt, yet unmet need, for systems and methods that can defect and reduce noise in MRI data acquisition in real time while the data is being acquired rather than during image reconstruction.

### SUMMARY OF THE INVENTION

The current invention is designed to meet this long-felt need. By measuring RF signals synchronized to the pulses produced by the MRI apparatus, the invention provides a system and method for identifying noise on the MRI signal and reducing the noise.

It is thus an object of the present invention to disclose a system for determining the level of shielding in an MRI apparatus and for real-time reduction of noise produced during MRI data acquisition, in an MRI apparatus comprising RF pulse generating means for generating RF pulses for MRI data acquisition and a cavity, wherein said system comprises: at least one antenna in location selected from the group consisting of (a) in proximity to said MRI apparatus and (b) within the cavity of said MRI apparatus; data acquisition means in communication with at least one antenna and in communication with said RF pulse generating means; and, synchronizing means for synchronizing the acquisition of data by said data acquisition means with MRI pulses being produced by said MRI apparatus It is a further object of this invention to disclose such a system, wherein said system comprises a first antenna located in proximity to said MRI apparatus and a second antenna located within the cavity of said MRI apparatus. In some embodiments of the system, the second antenna is not located within a field of view of said apparatus.

It is a further object of this invention to disclose such a system, wherein at least one of said antennas comprises three orthogonally oriented loop antennas.

It is a further object of this invention to disclose such a system, wherein at least one of said is an omnidirectional antenna.

It is a further object of this invention to disclose such a system, wherein said MRI apparatus comprises a permanent magnet.

It is a further object of this invention to disclose such a system, comprising data manipulation means configured for producing a residual signal obtained by said at least one antenna from which signals arising from said RF pulse generating means have been eliminated.

It is a further object of this invention to disclose a method for real-time reduction of noise during MRI data acquisition in an MRI apparatus comprising RF pulse generating means for generating RF pulses and a cavity, comprising: placing at least one antenna in a location selected from the group consisting of (a) in proximity to an MRI apparatus and (b) within the cavity of said MRI apparatus; connecting said antennas with data acquisition means and with said RF pulse generating means; synchronizing data acquisition with at least one RF pulse or set of MRI pulses produced by said RF pulse generating means to produce a data subset; determining residual noise measured by at least one of said antennas after said step of synchronizing; and if said residual noise is above a predetermined threshold, performing a step chosen from the group consisting of: (i) subtracting said residual noise from an MRI signal obtained following said MRI pulse or set of MRI pulses; (ii) repeating said MRI pulses to obtain said data subset; and (iii) deleting said data subset from a data set acquired during said MRI data acquisition.

It is a further object of this invention to disclose such a method, wherein said step of placing at least one antenna in a location selected from the group consisting of in proximity to said MRI apparatus and within the cavity of said MRI apparatus comprises placing a first antenna in proximity to said MRI apparatus and placing a second antenna within the cavity of said MRI apparatus. In some embodiments of the method, said step of placing a second antenna within the cavity of said MRI apparatus comprises placing said second antenna outside of a field of view of said MRI apparatus.

It is a further object of this invention to disclose such a method, wherein said step of placing at least one antenna in a location selected from the group consisting of in proximity to said MRI apparatus and within the cavity of said MRI apparatus comprises placing an antenna comprising three orthogonal loop antennas.

It is a further object of this invention to disclose such a method, said step of placing at least one antenna in a location selected from the group consisting of in proximity to said MRI apparatus and within the cavity of said MRI apparatus comprises placing an omindirectional antenna.

It is a further object of this invention to disclose such a method, wherein said MRI apparatus is a permanent magnet MRI apparatus.

It is a further object of this invention to disclose a method for determining the level of RF shielding in an MRI apparatus comprising RF pulse generating means for generating RF pulses and a cavity, wherein said method comprises placing a first antenna in proximity to said MRI apparatus; placing a second antenna within the cavity of said MRI apparatus; connecting said antennas with data acquisition means and with said RF pulse generating means; synchronizing data acquisition by said data acquisition means with at least one RF pulse or set of MRI pulses produced by said RF pulse generating means to produce a data subset; determining residual noise measured by each of said antennas after said step of synchronizing; and comparing the residual noise obtained by each of said antennas, thereby determining the level of RF shielding.

### BRIEF DESCRIPTION OF THE DRAWING

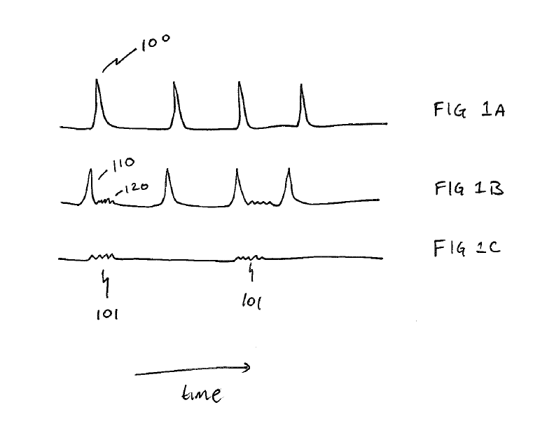

The invention will now be described with reference to the drawing, wherein FIGS. 1A, 1B and 1C provide a set of schematic illustrations of the relevant signals in the system and method herein disclosed.

### DETAILED DESCRIPTION OF THE PREFERRED EMBODIMENTS

In the following description, various aspects of the invention will be described. For the purposes of explanation, specific details are set forth in order to provide a thorough understanding of the invention. It will be apparent to one skilled in the art that there are other embodiments of the invention that differ in details without affecting the essential nature thereof. Therefore the invention is not limited by that which is illustrated in the figure and described in the specification, but only as indicated in the accompanying claims, with the proper scope determined only by the broadest interpretation of said claims.

The system herein disclosed comprises at least one antenna placed in proximity to, or within the cavity of, a standard MRI apparatus. In preferred embodiments, the system comprises antennas both within the cavity of and in proximity to the MRI apparatus. The antenna placed within the cavity of the MRI apparatus may be, but is not necessarily placed within, the instrument's field of view. In preferred embodiments of the invention, the antennas are omnidirectional, e.g. they may comprise three orthogonally oriented loop antennas (i.e. along the x, y, and z axes) to check all polarizations of RF signals impinging on the MRI apparatus.

The antennas are connected, by any means known in the art, to a standard data acquisition system that can measure and record the signals received by the antennas, preferably using a separate data for each antenna. The data acquisition system is also in communication with the RF generation system of the MRI apparatus, and also includes standard means for synchronizing the signals received from the antennas with the RF pulses produced by the MRI apparatus.

In preferred embodiments, the system additionally includes data manipulation means (e.g. a computer) programmed to remove signals produced by the RF pulse generating means from the signal produced by the antennas.

It is within the scope of the invention to disclose a method for real-time reduction of noise produced during MRI data acquisition using the system disclosed above. The method comprises placing the antennas either in proximity to, or within the cavity of, the MRI apparatus and connecting them to the data acquisition means, which is also placed in communication with the RF pulse generating system of the MRI apparatus. Measurements of ambient RF are then made using the antennas, which have been synchronized to the MRI pulses being generated by the RF pulse generating system of the MRI apparatus. By synchronizing the data measurement by the antennas to the MRI pulses, the signals arising from the MRI system itself are thereby eliminated. The signals from the antennas are then measured. If any of them is above a predetermined threshold, the signal is defined to be noisy, and the residual signal is defined as the noise.

Reference is now made to FIGS. 1A, 1B and 1C. FIG. 1A shows a schematic set of MRI pulses 100. FIG. 1B shows an unsynchronized data set from an antenna. The signal includes a pulses 110 arising from the MRI apparatus and noise 120 that can be, for example, random noise, persistent RF noise from a nearby apparatus, or noise due to transient fluctuations in the MRI magnetic field. FIG. 1C shows the synchronized data set. The influence of the MRI apparatus RF pulse generator has been removed by the synchronization, leaving signals 101 that are due to at least one source of noise. If the signals 101 are above a predetermined threshold, they are considered to be noise.

The noise can then be reduced or removed by any one of several methods. Non-limiting examples include the following. The set of pulses (e.g. those to produce a signal in a specific voxel) can be repeated; if the noise is random, then the repetition of the pulses should not have the noise. The data subset corresponding to the MRI data acquired after the set of pulses 100 can be deleted from the data set. Or, the noise can be removed by direct subtraction from the MRI signals.

It can be seen that the above system and method provide simple, reliable, and effective means and methods for providing real-time reduction or elimination of noise on an MRI signal during signal acquisition rather than during subsequent image reconstruction. The above system and method also provide simple, reliable, and effective means and methods for determining the actual level of shielding in an MRI apparatus, especially in those embodiments in which there are antennas both within and without the MRI apparatus; in these embodiments, the difference in the noise level between the signals produced by the two antennas will indicate the actual extent to which the MRI apparatus eliminates RF noise measured in the vicinity of, but outside of, the apparatus itself.

I claim:

1. A system for determining the level of shielding in an MRI apparatus and for real-time reduction of noise produced during MRI data acquisition in an MRI apparatus comprising RF pulse generating means for generating RF pulses for MRI data acquisition and a cavity, wherein said system comprises:
at least one antenna in location selected from the group consisting of (a) in proximity to said MRI apparatus and (b) within the cavity of said MRI apparatus;
data acquisition means in communication with at least one antenna and in communication with said RF pulse generating means; and,
synchronizing means for synchronizing the acquisition of data by said data acquisition means with MRI pulses being produced by said MRI apparatus.

2. The system according to claim 1, wherein said system comprises a first antenna located in proximity to said MRI apparatus and a second antenna located within the cavity of said MRI apparatus.

3. The system according to claim 1, wherein at least one of said antennas comprises three orthogonally oriented loop antennas.

4. The system according to claim 1, wherein at least one of said is an omnidirectional antenna.

5. The system according to claim 1, wherein said second antenna is not located within a field of view of said apparatus.

6. The system according to claim 1, wherein said MRI apparatus comprises a permanent magnet.

7. The system according to claim 1, comprising data manipulation means configured for producing a residual signal obtained by said at least one antenna from which signals arising from said RF pulse generating means have been eliminated.

8. A method for real-time reduction of noise during MRI data acquisition in an MRI apparatus comprising RF pulse generating means for generating RF pulses and a cavity, comprising:
placing at least one antenna in a location selected from the group consisting of (a) in proximity to said MRI apparatus and (b) within the cavity of said MRI apparatus;
connecting said antennas with data acquisition means and with said RF pulse generating means;
synchronizing data acquisition with at least one RF pulse or set of MRI pulses produced by said RF pulse generating means to produce a data subset;
determining residual noise measured by at least one of said antennas after said step of synchronizing; and,
if said residual noise is above a predetermined threshold, performing a step chosen from the group consisting of:
subtracting said residual noise from an MRI signal obtained following said MRI pulse or set of MRI pulses;
repeating said MRI pulses to obtain said data subset; and,
deleting said data subset from a data set acquired during said MRI data acquisition.

9. The method according to claim 8, wherein said step of placing at least one antenna in a location selected from the group consisting of (a) in proximity to said MRI apparatus and (b) within the cavity of said MRI apparatus comprises placing a first antenna in proximity to said MRI apparatus and placing a second antenna within the cavity of said MRI apparatus.

10. The method according to claim 9, wherein said step of placing a second antenna within the cavity of said MRI apparatus comprises placing said second antenna outside of a field of view of said MRI apparatus.

11. The method according to claim 8, wherein said step of placing at least one antenna in a location selected from the group consisting of (a) in proximity to said MRI apparatus and (b) within the cavity of said MRI apparatus comprises placing an antenna comprising three orthogonal loop antennas.

12. The method according to claim 8, said step of placing at least one antenna in a location selected from the group consisting of (a) in proximity to said MRI apparatus and (b) within the cavity of said MRI apparatus comprises placing at least one omindirectional antenna.

13. The method according to claim 8, wherein said MRI apparatus is a permanent magnet MRI apparatus.

14. A method for determining the level of RF shielding in an MRI apparatus comprising RF pulse generating means for generating RF pulses and a cavity, comprising:
placing a first antenna in proximity to said MRI apparatus;
placing a second antenna within the cavity of said MRI apparatus;
connecting said antennas with data acquisition means and with said RF pulse generating means;
synchronizing data acquisition by said data acquisition means with at least one RF pulse or set of MRI pulses produced by said RF pulse generating means to produce a data subset;
determining residual noise measured by each of said antennas after said step of synchronizing; and,
comparing the residual noise obtained by each of said antennas, thereby determining the level of RF shielding.
